(19) United States
(12) Patent Application Publication
(10) Pub. No.: US 2025/0380503 A1
(43) Pub. Date: Dec. 11, 2025

(54) SELF-ALIGNED BACKSIDE CUT

(71) Applicant: International Business Machines Corporation, Armonk, NY (US)

(72) Inventors: Reinaldo Vega, Mahopac, NY (US); Takashi Ando, Eastchester, NY (US); James P Mazza, Saratoga Springs, NY (US); Nicholas Anthony Lanzillo, Wynantskill, NY (US); David Wolpert, Poughkeepsie, NY (US)

(21) Appl. No.: 18/739,431

(22) Filed: Jun. 11, 2024

(51) Int. Cl. H01L 27/092; H01L 29/06; H01L 29/423; H01L 29/775; H01L 29/78; H01L 29/786

(52) U.S. Cl. CPC H10D 84/85; H10D 30/792; H10D 64/518; H10D 30/43; H10D 30/6735; H10D 30/6757; H10D 62/121

(57) ABSTRACT

Embodiments of the invention include a semiconductor structure a first transistor having a gate structure and a second transistor having the gate structure. The gate structure includes an upper portion and a lower portion, where the upper portion includes a first bottom surface and is outside an active region of the first transistor and the second transistor. The upper portion is between the first transistor and the second transistor, where the lower portion includes a second bottom surface and is inside the active region of the first transistor and the second transistor.

### BACKGROUND

The present invention generally relates to fabrication methods and resulting structures for integrated circuits (ICs), and more specifically, to fabrication methods and resulting structures configured and arranged for providing one or more self-aligned backside cuts.

ICs (also referred to as a chip or a microchip) include electronic circuits on a wafer. The wafer is a semiconductor material, such as, for example, silicon or other materials. An IC is formed of a large number of devices, such as transistors, capacitors, resistors, etc., which are formed in layers of the IC and interconnected with wiring in the back-end-of-line (BEOL) layers of the wafer. on the wafer. Typical ICs are formed by first fabricating individual semiconductor devices using processes referred to generally as the front-end-of-line (FEOL). A metal-oxide-semiconductor field-effect transistor (MOSFET) is a transistor used for amplifying or switching electronic signals. The MOSFET has a source, a drain, and a metal oxide gate electrode. A conventional FET is a planar device where the entire channel region of the device is formed parallel and slightly below the planar upper surface of the semiconducting substrate. In contrast to a planar FET, there are so-called three-dimensional (3D) devices, such as a FinFET device, which is a three-dimensional structure. One type of device that shows promise for advanced integrated circuit products is generally known as a nanosheet transistor. In general, a nanosheet transistor has a fin-type channel structure that includes a plurality of vertically spaced-apart sheets of semiconductor material. A gate structure for the device is positioned around each of these spaced-apart layers of channel semiconductor material.

### SUMMARY

Embodiments of the present invention are directed to providing one or more self-aligned backside cuts. A semiconductor structure includes a first transistor having a gate structure and a second transistor having the gate structure. The gate structure includes an upper portion and a lower portion, where the upper portion comprises a first bottom surface and is outside an active region of the first transistor and the second transistor, the upper portion being between the first transistor and the second transistor. The lower portion includes a second bottom surface and is inside the active region of the first transistor and the second transistor.

One or more embodiments provide a semiconductor structure. The semiconductor structure includes a first transistor and a second transistor having a gate structure, the first transistor having a first channel region, the second transistor having a second channel region. The semiconductor structure includes a non-conducting fill material formed in a cavity of the gate structure between the first transistor and the second transistor, a liner formed on an edge of the gate structure so as to be laterally displaced from the non-conducting fill material, and a metal fill material formed on the liner such that the first channel region intervenes between the metal fill material and the non-conducting fill material.

One or more embodiments provide a semiconductor structure. The semiconductor structure includes a first transistor and a second transistor having a gate structure on a substrate, the first transistor having a first channel region, the second transistor having a second channel region. The semiconductor structure includes a non-conducting fill material formed between the first transistor and the second transistor separating the gate structure into a first side for the first transistor and a second side for the second transistor, the non-conducting fill material being formed through the gate structure from a backside to a frontside of the substrate and being self-aligned to backside spacers. The semiconductor structure includes a first gate contact formed on the first side and a second gate contact formed on the second side.

Other embodiments of the present invention implement features of the above-described devices/structures in methods and/or implement features of the methods in devices/structures.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIGS. 1A, 1B, and 1C respectively depict a top view and cross-sectional views of a portion of an integrated circuit (IC) under-fabrication after fabrication operations according to one or more embodiments of the invention;

FIGS. 2A and 2B depict cross-sectional views of a portion of an IC under-fabrication after fabrication operations according to one or more embodiments of the invention;

FIGS. 3A and 3B depict cross-sectional views of a portion of an IC under-fabrication after fabrication operations according to one or more embodiments of the invention;

FIGS. 4A and 4B depict cross-sectional views of a portion of an IC under-fabrication after fabrication operations according to one or more embodiments of the invention;

FIGS. 5A and 5B depict cross-sectional views of a portion of an IC under-fabrication after fabrication operations according to one or more embodiments of the invention;

FIGS. 6A and 6B depict cross-sectional views of a portion of an IC under-fabrication after fabrication operations according to one or more embodiments of the invention;

FIGS. 7A and 7B depict cross-sectional views of a portion of an IC under-fabrication after fabrication operations according to one or more embodiments of the invention;

FIGS. 8A and 8B depict cross-sectional views of a portion of an IC under-fabrication after fabrication operations according to one or more embodiments of the invention;

FIGS. 9A and 9B depict cross-sectional views of a portion of an IC under-fabrication after fabrication operations according to one or more embodiments of the invention;

FIGS. 10A and 10B depict cross-sectional views of a portion of an IC under-fabrication after fabrication operations according to one or more embodiments of the invention;

FIGS. 11A and 11B depict cross-sectional views of a portion of an IC under-fabrication after fabrication operations according to one or more embodiments of the invention;

FIGS. 12A and 12B depict cross-sectional views of a portion of an IC under-fabrication after fabrication operations according to one or more embodiments of the invention;

FIGS. 13A and 13B depict cross-sectional views of a portion of an IC under-fabrication after fabrication operations according to one or more embodiments of the invention;

FIGS. 14A and 14B depict cross-sectional views of a portion of an IC under-fabrication after fabrication operations according to one or more embodiments of the invention;

FIGS. 15A and 15B depict cross-sectional views of a portion of an IC under-fabrication after fabrication operations according to one or more embodiments of the invention;

FIGS. 16A and 16B depict cross-sectional views of a portion of an IC under-fabrication after fabrication operations according to one or more embodiments of the invention;

FIGS. 17A and 17B depict cross-sectional views of a portion of an IC under-fabrication after fabrication operations according to one or more embodiments of the invention;

FIGS. 18A and 18B depict cross-sectional views of a portion of an IC under-fabrication after fabrication operations according to one or more embodiments of the invention;

FIGS. 19A and 19B depict cross-sectional views of a portion of an IC under-fabrication after fabrication operations according to one or more embodiments of the invention;

FIGS. 20A and 20B depict cross-sectional views of a portion of an IC under-fabrication after fabrication operations according to one or more embodiments of the invention; and

FIG. 21 depicts a cross-sectional view of an example backside cut having a realistic geometric shape according to one or more embodiments of the invention.

### DETAILED DESCRIPTION

Embodiments of the present disclosure are directed to a semiconductor structure. The semiconductor structure includes a first transistor having a gate structure and a second transistor having the gate structure. The gate structure includes an upper portion and a lower portion, where the upper portion includes a first bottom surface and is outside an active region of the first transistor and the second transistor. The upper portion is between the first transistor and the second transistor, where the lower portion includes a second bottom surface and is inside the active region of the first transistor and the second transistor. A technical effect and technical solution include an improvement in the effective capacitance of the first and second transistors which can be a PFET and an NFET. Gate material is removed outside the active region resulting in the upper portion and the lower portion, in order to achieve a reduced capacitance. The reduced capacitance reduces power consumption and increases performance. As a technical effect and technical solution, the present disclosure addresses/resolves edge capacitance in order to continue power scaling the semiconductor device, thereby providing complimentary metal-oxide-semiconductor (CMOS) scaling.

In addition to one or more of the features described above or below, or as an alternative, further embodiments disclose the first transistor and the second transistor comprise channel regions, the second bottom surface extending underneath the channel regions. A technical effect and technical solution include a reduction in capacitance based on the second bottom surface being different from the first bottom surface, as a result of a backside gate cut.

In addition to one or more of the features described above or below, or as an alternative, further embodiments disclose the first bottom surface is vertically above the second bottom surface. A technical effect and technical solution include a reduced capacitance for the semiconductor device based on removing material of the gate resulting in the first bottom surface being vertically above the second bottom surface.

In addition to one or more of the features described above or below, or as an alternative, further embodiments disclose a non-conducting fill material is underneath the upper portion, the non-conducting fill material being outside the active region of the first transistor and the second transistor. A technical effect and technical solution include a reduced capacitance for the semiconductor device based on removing material of the gate and filling the cavity with non-conducting fill material underneath the upper portion.

In addition to one or more of the features described above or below, or as an alternative, further embodiments disclose the non-conducting fill material is around a metal fill material. A technical effect and technical solution include support for additional wiring, such as signal wiring or power wiring.

In addition to one or more of the features described above or below, or as an alternative, further embodiments disclose: backside spacers are formed on a side of a substrate, the first transistor and the second transistor being above the substrate; and a boundary between the upper portion and the lower portion of the gate structure is self-aligned to the backside spacers. A technical effect and technical solution include a reduced capacitance for the semiconductor device based on removing material of the gate and filling the cavity with non-conducting fill material underneath the upper portion. The backside spacers provide self-alignment for forming the cavity and then filling the cavity with the non-conducting fill material (and/or other materials discussed herein).

In addition to one or more of the features described above or below, or as an alternative, further embodiments disclose a non-conducting fill material is formed on an edge of the gate structure so as to be laterally displaced from the upper portion. A technical effect and technical solution include a reduced capacitance for the semiconductor device particularly a reduced edge capacitance.

In addition to one or more of the features described above or below, or as an alternative, further embodiments disclose the non-conducting fill material comprises compressive stress. A technical effect and technical solution include enhancement of electrical current flow in a transistor based on the compressive stress.

In addition to one or more of the features described above or below, or as an alternative, further embodiments disclose the non-conducting fill material comprises tensile stress. A technical effect and technical solution include enhancement of electrical current flow in a transistor based on the tensile stress.

In addition to one or more of the features described above or below, or as an alternative, further embodiments disclose: the first transistor comprises a first source/drain region and the second transistor comprises a second source/drain region; and a first non-conducting fill material is formed between the first source/drain region and the second source/drain region so as to be self-aligned to first backside spacers, the first non-conducting fill material being formed underneath the upper portion. A technical effect and technical solution include a reduced capacitance for the semiconductor device.

In addition to one or more of the features described above or below, or as an alternative, further embodiments disclose: a second non-conducting fill material is formed on a sidewall of the first source/drain region so as to be self-aligned with another backside spacer, the second non-conducting fill material being laterally displaced from the first non-conducting fill material; and the second non-conducting fill material comprises compressive or tensile stress. A technical effect and technical solution include a reduced capacitance for the semiconductor device.

Embodiments of the present disclosure are directed to a method of forming a semiconductor device. The method includes providing a first transistor having a gate structure. The method includes providing a second transistor having the gate structure, the gate structure including an upper portion and a lower portion. The upper portion includes a first bottom surface and is outside an active region of the first transistor and the second transistor, the upper portion being between the first transistor and the second transistor. The lower portion includes a second bottom surface and is inside the active region of the first transistor and the second transistor. A technical effect and technical solution include an improvement in the effective capacitance of the first and second transistors which can be a PFET and NFET. Gate material is removed outside the active region resulting in the upper portion and the lower portion, in order to achieve a reduced capacitance. The reduced capacitance reduces power consumption and increases performance. As a technical effect and technical solution, the present disclosure addresses/resolves edge capacitance in order to continue power scaling the semiconductor device, thereby providing CMOS scaling.

In addition to one or more of the features described above or below, or as an alternative, further embodiments disclose the first transistor and the second transistor comprise channel regions, the second bottom surface extending underneath the channel regions. A technical effect and technical solution include a reduction in capacitance based on the second bottom surface being different from the first bottom surface, as a result of a backside gate cut.

In addition to one or more of the features described above or below, or as an alternative, further embodiments disclose the first bottom surface is vertically above the second bottom surface. A technical effect and technical solution include a reduced capacitance for the semiconductor device based on removing material of the gate, resulting in the first bottom surface being vertically above the second bottom surface.

In addition to one or more of the features described above or below, or as an alternative, further embodiments disclose a non-conducting fill material is underneath the upper portion, the non-conducting fill material being outside the active region of the first transistor and the second transistor. A technical effect and technical solution include a reduced capacitance for the semiconductor device based on removing material of the gate and filling the cavity with non-conducting fill material underneath the upper portion.

In addition to one or more of the features described above or below, or as an alternative, further embodiments disclose the non-conducting fill material is around a metal fill material. A technical effect and technical solution include support for additional wiring, such as signal wiring or power wiring.

In addition to one or more of the features described above or below, or as an alternative, further embodiments disclose: backside spacers are formed on a side of a substrate, the first transistor and the second transistor being above the substrate; and a boundary between the upper portion and the lower portion of the gate structure is self-aligned to the backside spacers. A technical effect and technical solution include a reduced capacitance for the semiconductor device based on removing material of the gate and filling the cavity with non-conducting fill material underneath the upper portion. The backside spacers provide self-alignment for forming the cavity and then filling the cavity with the non-conducting fill material (and/or other materials discussed herein).

In addition to one or more of the features described above or below, or as an alternative, further embodiments disclose a non-conducting fill material is formed on an edge of the gate structure so as to be laterally displaced from the upper portion. A technical effect and technical solution include a reduced capacitance for the semiconductor device based on the non-conducting fill material.

In addition to one or more of the features described above or below, or as an alternative, further embodiments disclose the non-conducting fill material comprises compressive stress. A technical effect and technical solution include enhancement of electrical current flow in a transistor based on the compressive stress.

In addition to one or more of the features described above or below, or as an alternative, further embodiments disclose the non-conducting fill material comprises tensile stress. A technical effect and technical solution include enhancement of electrical current flow in a transistor based on the tensile stress.

In addition to one or more of the features described above or below, or as an alternative, further embodiments disclose: the first transistor comprises a first source/drain region and the second transistor comprises a second source/drain region; and a first non-conducting fill material is formed between the first source/drain region and the second source/drain region so as to be self-aligned to first backside spacers, the first non-conducting fill material being formed underneath the upper portion. A technical effect and technical solution include a reduced capacitance for the semiconductor device.

In addition to one or more of the features described above or below, or as an alternative, further embodiments disclose: a second non-conducting fill material is formed on a sidewall of the first source/drain region so as to be self-aligned with another backside spacer, the second non-conducting fill material being laterally displaced from the first non-conducting fill material; and the second non-conducting fill material comprises compressive or tensile stress. A technical effect and technical solution include a reduced capacitance for the semiconductor device.

Embodiments of the present disclosure are directed to a semiconductor structure. The semiconductor structure includes a first transistor and a second transistor having a gate structure, the first transistor having a first channel region, the second transistor having a second channel region. The semiconductor structure includes a non-conducting fill material formed in a cavity of the gate structure between the first transistor and the second transistor, a liner formed on an edge of the gate structure so as to be laterally displaced from the non-conducting fill material, and a metal fill material formed on the liner such that the first channel region intervenes between the metal fill material and the non-conducting fill material. A technical effect and technical solution include an improvement in the effective capacitance of the first and second transistors which can be a PFET and NFET. Gate material is removed outside the active region resulting in the upper portion and the lower portion, in order to achieve a reduced capacitance. The reduced capacitance allows greater transistor density. As a technical effect and technical solution, the present disclosure addresses/resolves edge capacitance in order to continue power scaling the semiconductor device, thereby providing complimentary metal-oxide-semiconductor (CMOS) scaling. A technical effect and technical solution include support for additional wiring, such as signal wiring or power wiring.

In addition to one or more of the features described above or below, or as an alternative, further embodiments disclose the liner is self-aligned to a first backside spacer and the non-conducting fill material is self-aligned to a second backside spacer. A technical effect and technical solution include self-alignment from the backside, based on self-aligned cuts and subsequent self-aligned deposition.

Embodiments of the present disclosure are directed to a method of forming a semiconductor structure. The method includes providing a first transistor and a second transistor having a gate structure, the first transistor having a first channel region, the second transistor having a second channel region. The method includes forming a non-conducting fill material in a cavity of the gate structure between the first transistor and the second transistor, forming a liner on an edge of the gate structure so as to be laterally displaced from the non-conducting fill material, and forming a metal fill material on the liner such that the first channel region intervenes between the metal fill material and the non-conducting fill material. A technical effect and technical solution include an improvement in the effective capacitance of the first and second transistors which can be a PFET and NFET. Gate material is removed outside the active region resulting in the upper portion and the lower portion, in order to achieve a reduced capacitance. The reduced capacitance allows greater transistor density. As a technical effect and technical solution, the present disclosure addresses/resolves edge capacitance in order to continue power scaling the semiconductor device, thereby providing complimentary metal-oxide-semiconductor (CMOS) scaling. A technical effect and technical solution include support for additional wiring, such as signal wiring or power wiring.

In addition to one or more of the features described above or below, or as an alternative, further embodiments disclose the liner is self-aligned to a first backside spacer and the non-conducting fill material is self-aligned to a second backside spacer. A technical effect and technical solution include self-alignment from the backside, based on self-aligned cuts and subsequent self-aligned deposition.

Embodiments of the present disclosure are directed to a semiconductor structure. The semiconductor structure includes a first transistor and a second transistor having a gate structure on a substrate, the first transistor having a first channel region, the second transistor having a second channel region. The semiconductor structure includes a non-conducting fill material formed between the first transistor and the second transistor separating the gate structure into a first side for the first transistor and a second side for the second transistor, the non-conducting fill material being formed through the gate structure from a backside to a frontside of the substrate and being self-aligned to backside spacers. The semiconductor structure includes a first gate contact formed on the first side and a second gate contact formed on the second side. A technical effect and technical solution include an improvement in the effective capacitance of the first and second transistors which can be a PFET and NFET. Gate material is removed outside the active region resulting in the upper portion and the lower portion, in order to achieve a reduced capacitance. The reduced capacitance allows greater transistor density. As a technical effect and technical solution, the present disclosure addresses/resolves edge capacitance in order to continue power scaling the semiconductor device, thereby providing complimentary metal-oxide-semiconductor (CMOS) scaling.

In addition to one or more of the features described above or below, or as an alternative, further embodiments disclose a metal fill material extending through the non-conducting fill material from the backside to the frontside and a contact via formed in contact with the metal fill material on the frontside. A technical effect and technical solution include support for additional wiring between a frontside and backside, such as signal wiring or power wiring.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

The MOSFET is a transistor used for amplifying or switching electronic signals. The MOSFET has a source, a drain, and a metal gate electrode. The metal gate is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (NFET) and p-type field effect transistors (PFET) are two types of complementary MOSFETs. The NFET includes n-doped source and drain junctions and uses electrons as the current carriers. The PFET includes p-doped source and drain junctions and uses holes as the current carriers.

The nanowire or nanosheet MOSFET is a type of MOSFET that uses multiple stacked nanowires/nanosheets to form multiple channel regions. The gate regions of a nanosheet MOSFET are formed by wrapping gate stack materials around the multiple nanowire/nanosheet channels. This configuration is known as a gate-all-around (GAA) FET structure. The nanowire/nanosheet MOSFET device mitigates the effects of short channels and reduces drain-induced barrier lowering.

The GAA nanosheet FET structures can provide superior electrostatics. In contrast to known Fin-type FET (FinFET) structures in which the fin element of the transistor extends “up” out of the transistor, nanosheet FET designs implement the fin as a silicon nanosheet/nanowire. In a known configuration of a GAA nanosheet FET, a relatively small FET footprint is provided by forming the channel region as a series of nanosheets (i.e., silicon nanowires). A known GAA configuration includes a source region, a drain region, and stacked nanosheet channels between the source and drain regions. A gate surrounds the stacked nanosheet channels and regulates electron flow through the nanosheet channels between the source and drain regions. GAA nanosheet FETs are fabricated by forming alternating layers of channel nanosheets and sacrificial nanosheets. The sacrificial nanosheets are released from the channel nanosheets before the FET device is finalized.

Turning now to an overview of technologies that are more specifically relevant to aspects of the present disclosure, ICs are fabricated in a series of stages, including a front-end-of-line (FEOL) stage, a middle-of-line (MOL) stage, and a back-end-of-line (BEOL) stage. The process flows for fabricating modern ICs are often identified based on whether the process flows fall in the FEOL stage, the MOL stage, or the BEOL stage. Generally, the FEOL stage is where device elements (e.g., transistors, capacitors, resistors, etc.) are patterned in the semiconductor substrate/wafer. The FEOL stage processes include wafer preparation, isolation, gate patterning, and the formation of wells, source/drain (S/D) regions, extension junctions, silicide regions, and liners. The MOL stage typically includes process flows for forming the contacts (e.g., CA) and other structures that communicatively couple to active regions (e.g., gate, source, and drain) of the device element. For example, the silicidation of source/drain regions, as well as the deposition of metal contacts, can occur during the MOL stage to connect the elements patterned during the FEOL stage. Layers of interconnections (e.g., metallization layers) are formed above these logical and functional layers during the BEOL stage to complete the IC. Most ICs need more than one layer of wires to form all the necessary connections, and as many as 5-12 layers are added in the BEOL process. The various BEOL layers are interconnected by vias that couple from one layer to another. Insulating dielectric materials are used throughout the layers of an IC to perform a variety of functions, including stabilizing the IC structure and providing electrical isolation of the IC elements. For example, the metal interconnecting wires in the BEOL region of the IC are isolated by dielectric layers to prevent the wires from creating a short circuit with other metal layers.

One or more embodiments provide transistors with a self-aligned backside cut. A backside spacer self-aligns a gate cut from the backside of the gate outside of the active region. The self-aligned backside gate cut into the gate can be a partial gate cut or a full gate cut using, for example, reactive ion etching (RIE). The backside spacers allows for aggressive etching near the active region. As a technical effect and technical solution, this provide reduced gate overhang and enables lower effective capacitance (C_{eff}) options. This allows flexibility for gate contact (CB) placement.

In one or more embodiments, techniques can use shallow trench isolation regions as a template for self-alignment of the gate cut from the backside, which can be supplemented by using backside spacers to define the backside cut fill and the distance to the active region. As technical effects and technical solutions, this enables the self-aligned gate cut fill outside of the active region (RX) without compromising the GAA structure. This reduces edge capacitance, thereby enabling additional power scaling for narrow active regions, and this enables additional cell height scaling. Also, one or more embodiments are applicable to self-aligned epitaxial cuts, thereby additionally reducing the source/drain contact (CA) depth over the shallow trench isolation region, which is another source of parasitic capacitance. In addition to removing gate material, the self-aligned epitaxial cut is a cut that removes overhang of the NFET epitaxial material past the active region, overhang of the PFET epitaxial material past the active region, and a bottom portion of the source/drain contact. The removed materials are replaced with the gate cut fill material. When the transistors are scaled down, it is possible that the NFET and PFET epitaxial materials could touch (i.e., short circuit); however, embodiments have the technical effect and solution of replacing the removed epitaxial materials with the gate cut fill material, such as a dielectric material. This serves to further isolate the PFET and NFET epitaxial materials from one another.

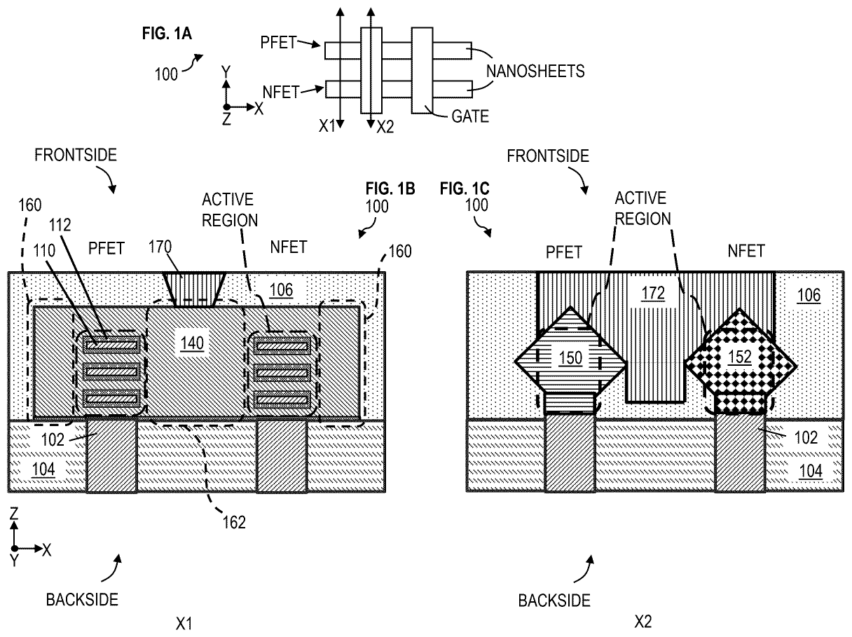

Turning now to a more detailed description of aspects of the present invention, FIG. 1A depicts a top view of a simplified illustration of a portion of an integrated circuit (IC) 100, FIG. 1B depicts a cross-sectional view taken along X1 of the IC 100, and FIG. 1C depicts a cross-sectional view taken along X2 of the IC 100. For ease of understanding, some layers may be omitted from the top view so as not to obscure the figure and to view layers underneath. As such, the top view is intended to provide a simplified illustration and a general orientation, but the top view is not intended to be a complete representation of the device. Standard semiconductor fabrication techniques can be utilized to fabricate the IC 100 as understood by one of ordinary skill in the art. Any suitable lithography processes including deposition techniques and etching techniques can be utilized herein.

FIGS. 1A, 1B, and 1C depict the IC 100 having a wafer where several fabrication processes have been performed. The figures illustrate the IC 100 after nanosheet stack growth and nanosheet patterning. A nanosheet stack is formed on a substrate 102 (or wafer). The substrate 102 may be formed of (pure) silicon. Other suitable semiconductor materials can be utilized for the substrate 102. As seen in FIGS. 1B and 1C, a nanosheet stack of semiconductor layers 110 is formed. The semiconductor layers 110 may include substantially pure silicon. The semiconductor layers 110 are the channel regions for the nanosheet FET device. The semiconductor layers 110 are nanosheets, and the nanosheets can have a thickness of, for example, 5 nanometers. The thickness of a nanosheet can range from about 2-10 nm, and other ranges are possible.

A dielectric stack 112 surrounds the semiconductor layers 110 that form channel regions, and a gate structure 140 wraps around the dielectric stack 112 and semiconductor layers 110. The dielectric stack 112 includes a high-k dielectric layer surrounding the semiconductor layers 110, and a thin oxide layer may be an intervening layer between the semiconductor layers 110 and the high-k dielectric layer. The gate structure 140 includes work function materials and a gate metal fill. The work function materials can be p-type and/or n-type materials.

The IC 100 can include many transistors such as a p-type FET (PFET) and an n-type FET (NFET), each having its own channel regions of semiconductor layers 110. Source/drain regions 150 and 152 are epitaxial materials grown on the sides of the semiconductor layers 110 so as to source and drain electrical current. The epitaxial material can be doped with n-type or p-type dopants according to whether an n-type or p-type transistor is being formed. For example, the source/drain regions 150 can be doped with p-type dopants for the PFET, while the source/drain regions 152 can be doped with n-type dopants for the NFET.

The PFET and NFET both have active areas. The active region of a transistor is utilized for and/or to control the flow of electrical current in the PFET and NFET, respectively. The channel regions of the PFET and the surrounding material are in the active region and contribute to the flow of electrical current. Similarly, the channel regions of the NFET and the surrounding material are in the active region and contribute to the flow of electrical current. Outside of the active region of the channel regions, there can be edge capacitance represented by dashed lines 160 in the gate, and there can be capacitance in the gate between the channel regions of the PFET and NFET represented by dashed lines 162. As transistor size scales down, the edge capacitance stays the same. This results in an issue in which capacitance does not scale at the same rate as the device size and eventually hits a floor. Capacitance is related to the ability to reduce power consumption in the device, so it would be beneficial to reduce capacitance thereby by reducing power consumption for the scaled-down device. In accordance with one or more embodiments, the present disclosure describes techniques for cutting the edges of the gate in a self-aligned manner from the backside of the wafer in order to then provide scaling for the cell height (in the x-axis with respect to the spacing between the north and south cell boundaries). For example, when the edge capacitance is reduced, the cell height can be further reduced in the x-axis. By reducing the capacitance, the transistor density can be increased such that more transistors can be formed in a smaller footprint on the semiconductor device. Because of the difficulty in aligning a cut from the frontside with top-down pattern, one or more embodiments utilize backside spacers for self-alignment of the gate cut and backside gate cut fill.

Further, shallow trench isolation (STI) regions 104 are formed in the substrate 102. Interlayer dielectric (ILD) layer 106 fills areas around the gate structure 140, the source/drain regions 150, and the source/drain regions 152. The STI regions 104 and the ILD layer 106 can include low-k dielectric materials, ultra-low-k dielectric materials, etc. A gate contact 170 is formed in the ILD layer 106 to be in contact with the gate structure 140, and a source/drain contact 172 is formed in the ILD layer 106 to be in contact with the source/drain regions 150 and 152. The gate contact 170 and the source/drain contact 172 can be formed of metals and metal alloys including tungsten, titanium, titanium nitride, nickel, copper, gold, aluminum, etc., with appropriate liners.

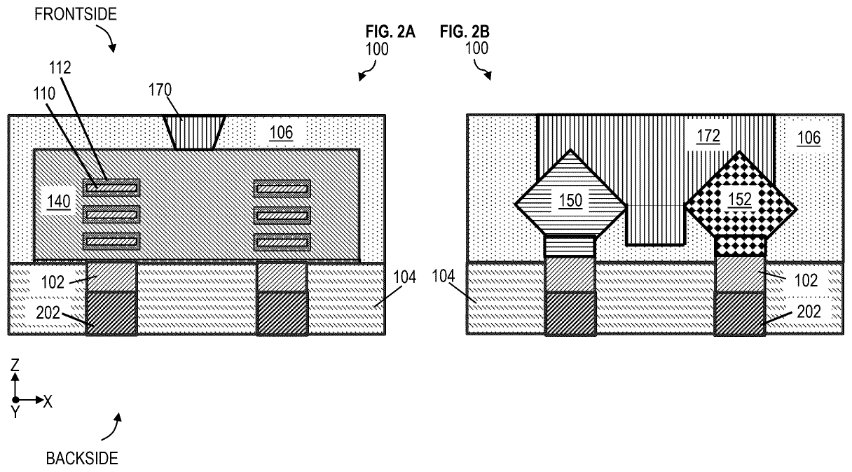

FIGS. 2A and 2B depict the IC 100 after wafer flip and recess on the backside. Although it is understood that fabrication processes are formed on the backside of the wafer, the orientation of the figures is not flipped in the figures so as to assist the reader. Etching is performed to selectively recess the substrate 102, thereby creating a cavity. Deposition is performed to fill the cavity with a backside cap layer 202. The backside cap layer 202 can include a nitride material such as silicon nitride (SiN). The backside cap layer 202 serves to protect the substrate 102 during subsequent fabrication processes.

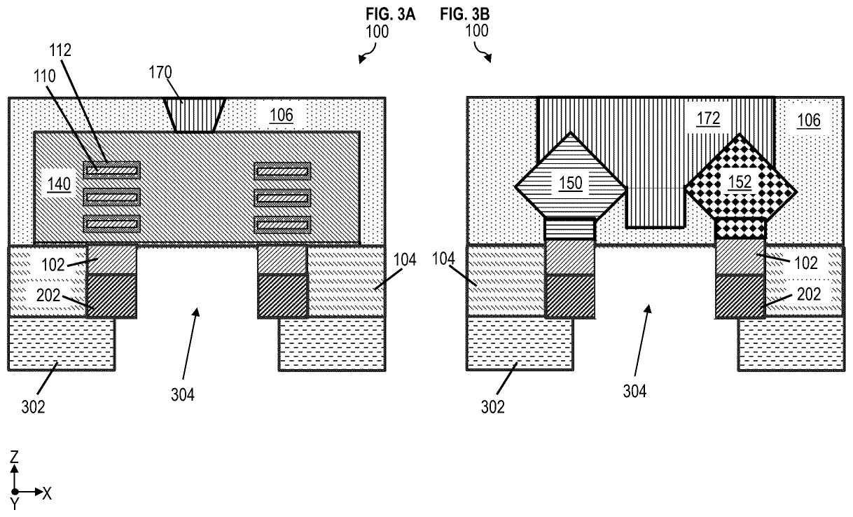

FIGS. 3A and 3B depict the IC 100 after selective removal of shallow trench isolation regions between the NFET and PFET source/drain. A block mask 302 is deposited and patterned in preparation for etching. Etching is performed to selectively etch the STI region 104 stopping on the gate structure 140 and stopping on the ILD layer 106, thereby forming a cavity 304. A reactive ion etch (RIE) can be performed to etch the cavity 304. The block mask 302 can include a stack of materials. Example materials of the block mask 302 can include an organic patterning layer (OPL), antireflective coating, and/or a photoresist layer, along with other known materials.

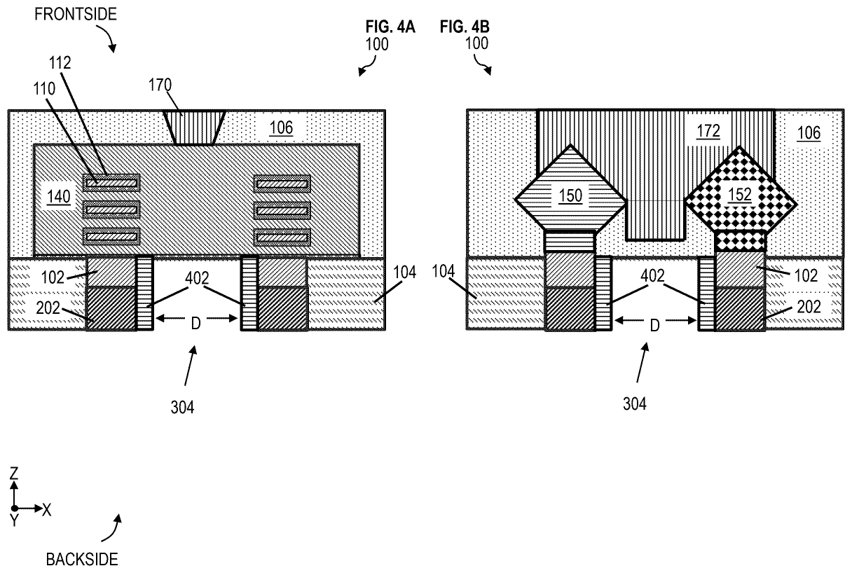

FIGS. 4A and 4B depict the IC 100 after inner backside spacer formation. The block mask 302 is removed. The block mask 302 can be stripped or removed by ashing. Spacer material is deposited conformally and an anisotropic etch is performed to remove the spacer material from the horizontal surfaces, thereby forming (inner) backside spacers 402 on the sidewalls of the cavity 304. The thickness of the backside spacers 402 in the x-axis determines the width of a subsequent cavity that is to be filled to form the subsequent backside cut fill material. The thickness of the backside spacers 402 determines a distance “D” of the opening between the backside spacers 402. Example spacer materials of the backside spacers 402 may include nitride materials, low-k dielectric nitrides, and silicon nitride. Further example spacer materials of the backside spacers 402 may include SiBCN, SiOCN, SiOC, SiC, etc. Optionally, the material of the backside spacers 402 is to provide etch selectivity for subsequent etching.

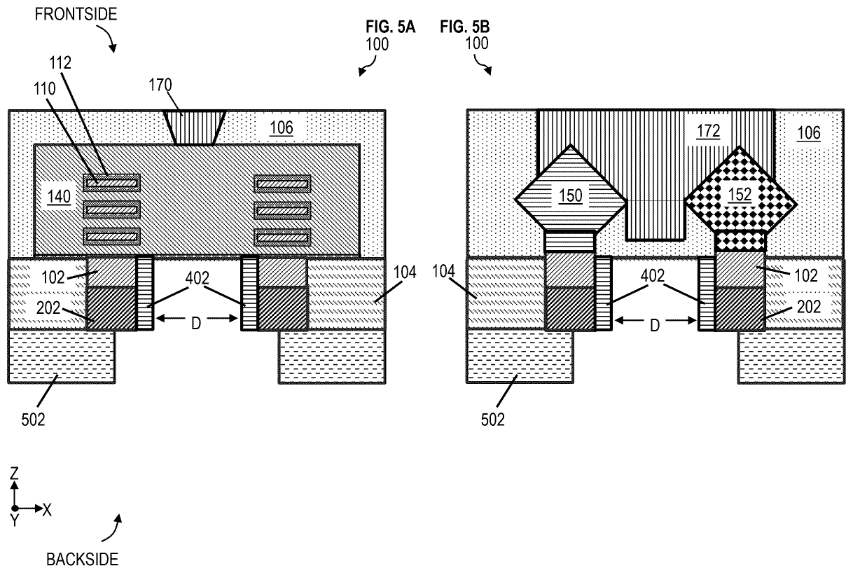

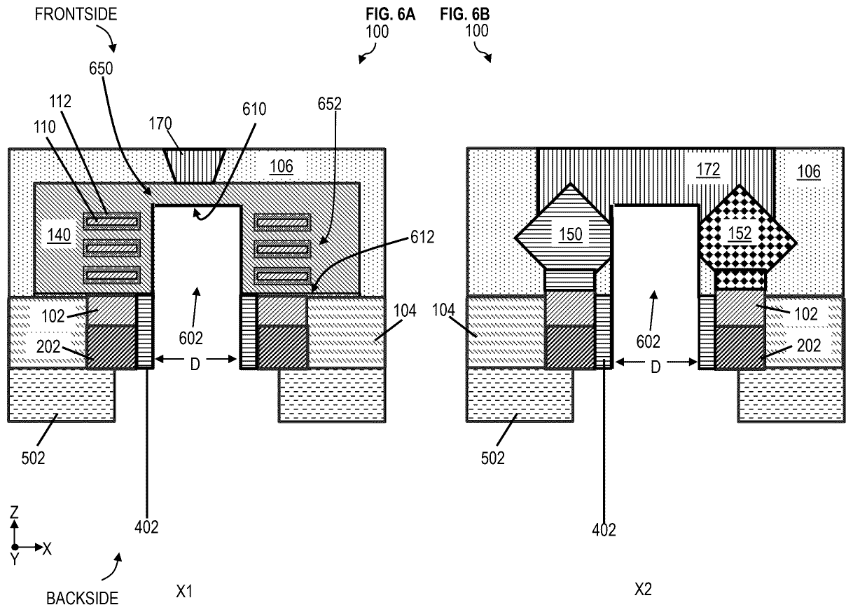

FIGS. 5A and 5B depict the IC 100 after block mask deposition and patterning. A block mask 502 is deposited on the backside and patterned in preparation for etching to form cavity 602 in FIGS. 6A and 6B. The block mask 502 can include any of the example materials of the block mask 302.

FIGS. 6A and 6B depict the IC 100 after can self-aligned partial reactive ion etching. Using the backside spacers 402 as a guide, a backside anisotropic etch, for example a RIE, is performed to form the cavity 602. As can be seen in FIG. 6A, the etching is performed to selectively remove part of the gate structure 140 between the semiconductor layers 110 (e.g., respective channel regions) of the PFET and NFET, according to position of the backside spacers 402. As can be seen in FIG. 6B, the etching is performed to selectively remove part of the ILD layer 106 and the source/drain contact 172 between the source/drain regions 150 and 152 of the PFET and NFET, respectively, according to position of the backside spacers 402. As seen in FIG. 6B, overhanging portions of the (PFET) source/drain region 150 and the (NFET) source/drain region 152 are removed during the etch based on guide of the backside spacers 402.

As noted above, the backside spacers 402 control the width of the cavity 602 in the x-axis, where the width along the x-axis is a lateral dimensional in FIGS. 6A and 6B. Particularly, the thickness of the backside spacers 402 in the x-axis can be increased or decreased to control the width of the cavity 602 in the x-axis. When the thickness of the backside spacers 402 is decreased resulting in a greater distance D in the x-axis, the width of the backside cut forming the cavity 602 is wider. In contrast, when the thickness of the backside spacers 402 is increased resulting in a smaller distance D, the width of the backside cut forming the cavity 602 is smaller.

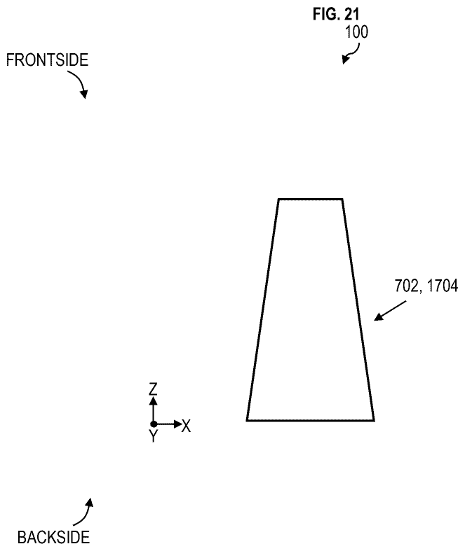

The etching is a backside gate cut into the gate structure 140, which removes gate material outside of the active regions of the PFET and NFET, thereby reducing the capacitance depicted by dashed lines 162 in FIG. 1B. After performing the etch, the gate structure 140 has an upper portion 650 between the channel regions of semiconductor layers 110 of the PFET and NFET. The upper portion 650 of the gate structure 140 has a bottom surface 610. The etching also results in a lower portion 652 of the gate structure 140, and the lower portion 652 has a bottom surface 612 that is below the bottom surface 610 of the upper portion 650. The bottom surface 612 extends under the respective channel regions of the PFET and NFET each having its own lower portion (e.g., lower portion 652) of the gate structure 140. The inside boundary of the backside spacers 402 defines the boundary connecting the bottom surface 610 of the upper portion 650 to the bottom surface 612 of the lower portion 652. Although FIGS. 6A and 6B depict a rectangular geometric shape for the cavity 602, the gate cut from the backside results in more of a trapezoidal geometric shape as depicted in FIG. 21, where the width at the backside is greater than the width toward the frontside.

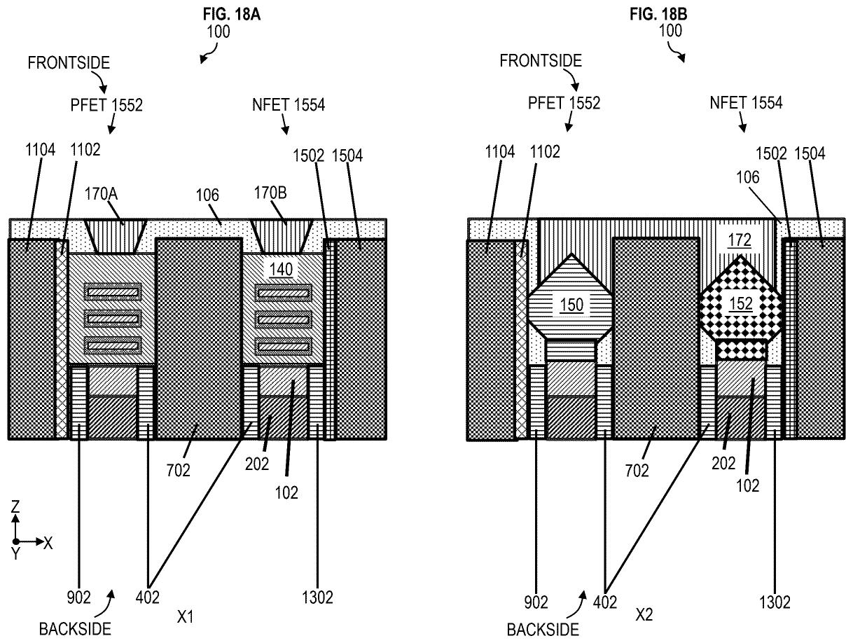

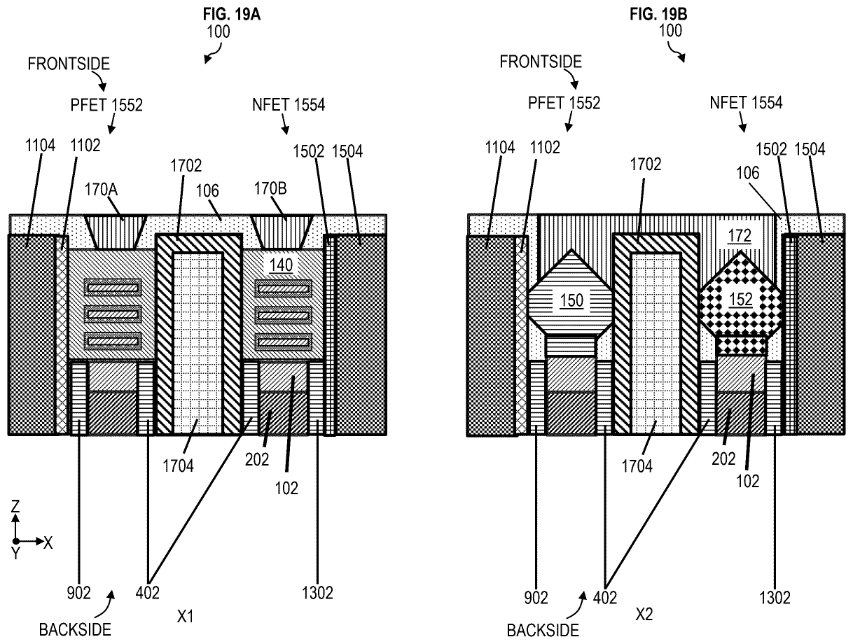

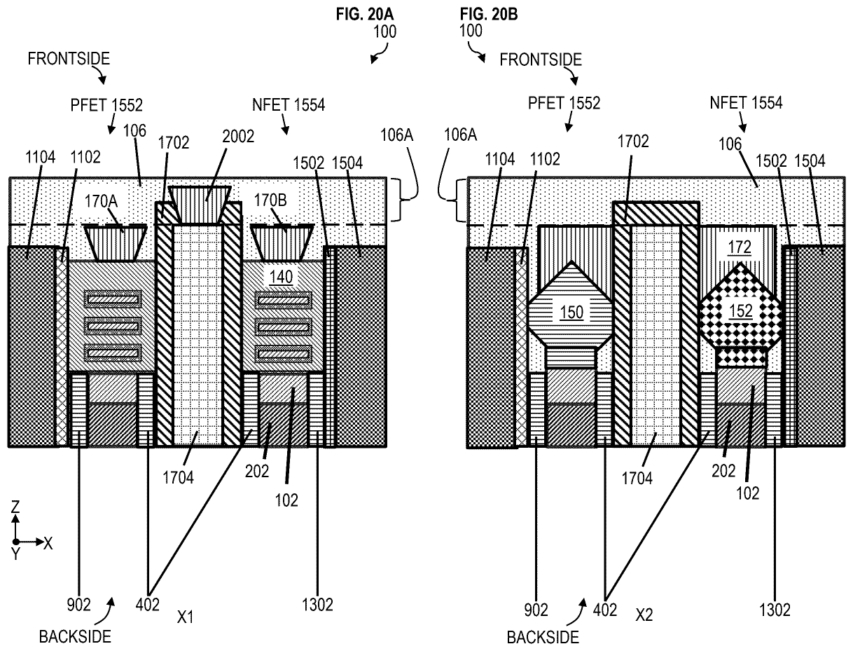

The example in FIGS. 6A and 6B may be considered a partial etch, because the etching stops before breaking through the gate structure 140. In one or more embodiments, etching can continue until gate break through as depicted in FIGS. 18A and 18B and FIGS. 19A and 19B. In one or more embodiments, etching can continue with both gate break through and source/drain contact break through as depicted in FIGS. 20A and 20B. It is noted that, in any of the examples, the etching is from the backside of the wafer (transistor) with self-alignment of the cavity 602 defined by the distance D between the backside spacers 402.

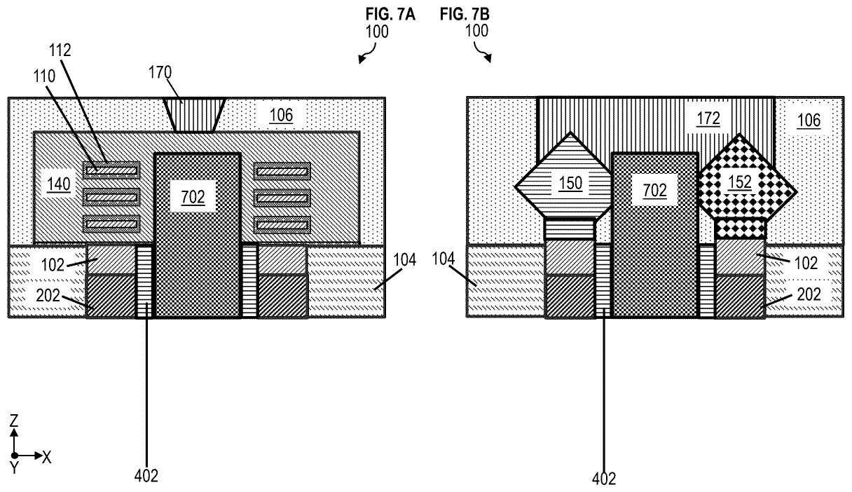

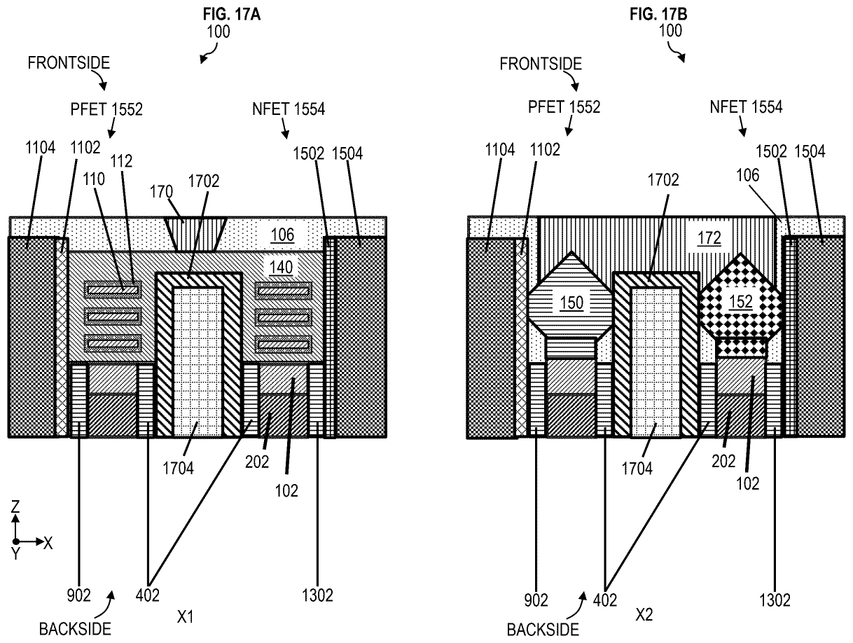

FIGS. 7A and 7B depict the IC 100 after filling the cavity and performing chemical mechanical polishing/planarization (CMP). The block mask 502 is removed. Deposition is performed to deposit a low-k dielectric material that fills the cavity 602, and polishing/planarization (e.g., CMP) is performed to level the low-k dielectric material resulting in backside fill material 702. The backside fill material 702 fills the cavity 602 (i.e., the backside cut) depicted in FIGS. 6A and 6B and replaces the gate structure 140 that was previously removed. The materials of the backside fill material 702 can include low-k dielectric materials, ultra-low-k dielectric materials, etc. The material of the backside fill material 702 is intended to be a non-conducting material. In one or more embodiments, the backside fill material can be a backside metal fill 1704 as depicted in FIGS. 17A and 17B, FIGS. 19A and 19B, and FIGS. 20A and 20B, and the backside metal fill 1704 is a conducting material.

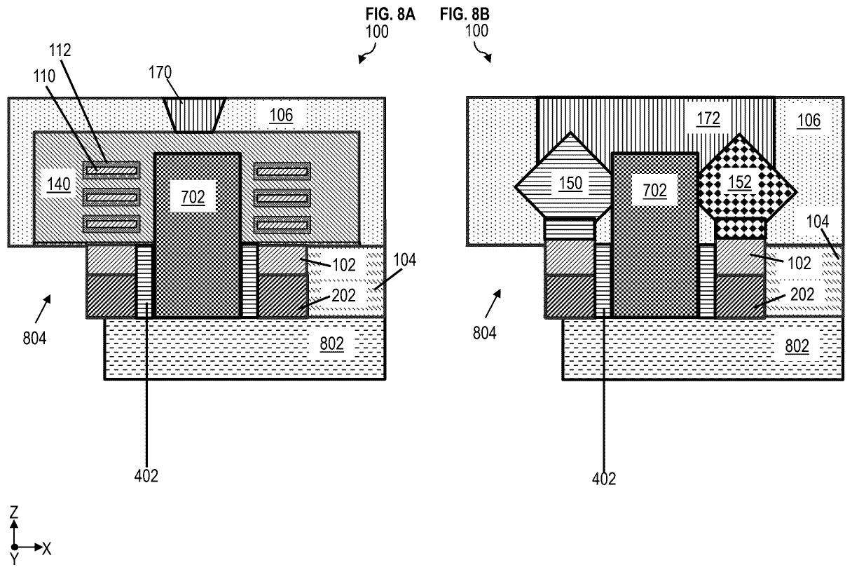

FIGS. 8A and 8B depict the IC 100 after block mask deposition and patterning for the PFET. A block mask 802 is deposited and patterned. The block mask 802 can include any of the example materials of the block mask 302. Selective etching is performed to remove part of the STI region 104, thereby creating cavity 804. As seen in FIG. 8A, the etching stops on the gate structure 140 and the ILD layer 106 in the cavity 804. As seen in FIG. 8B, the etch stops on the ILD layer 106 in the cavity 804.

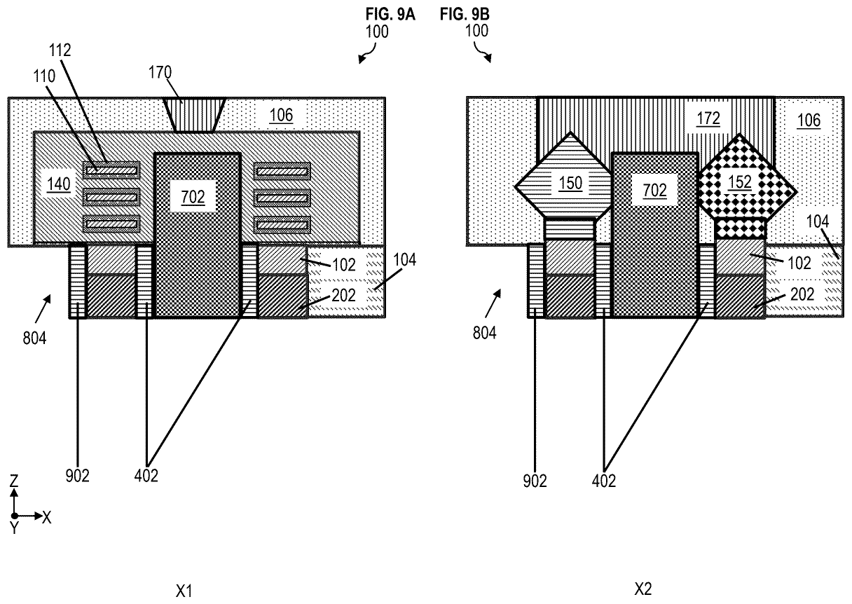

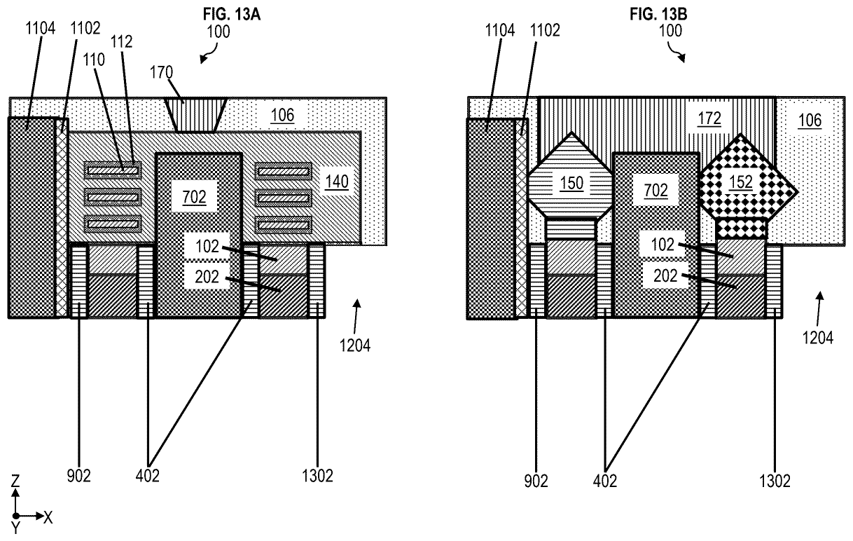

FIGS. 9A and 9B depict the IC 100 after outer backside spacer formation for the PFET. The block mask 802 is removed. Spacer material is deposited conformally, and an anisotropic etch is performed to remove the spacer material from the horizontal surfaces, thereby forming (outer) backside spacer 902 on the sidewalls of the cavity 804. The thickness of the backside spacer 902 in the x-axis determines the width/boundary of a subsequent cavity that is filled to form subsequent outer backside cut fill material. Example spacer materials of the backside spacer 902, as well as backside spacer 1302 in FIGS. 13A and 13B for the NFET, may include nitride materials, low-k dielectric nitrides, and silicon nitride. Further example spacer materials of the backside spacer 902, as well as the backside spacer 1302 in FIGS. 13A and 13B, may include SiBCN, SiOCN, SiOC, SiC, etc. The material of the backside spacer 902 is to provide etch selectivity for subsequent etching. In one or more embodiments, the thickness in the x-axis of the backside spacer 902, as well as the backside spacer 1302 in FIGS. 13A and 13B, can be different from or about the same as the thickness of the backside spacers 402.

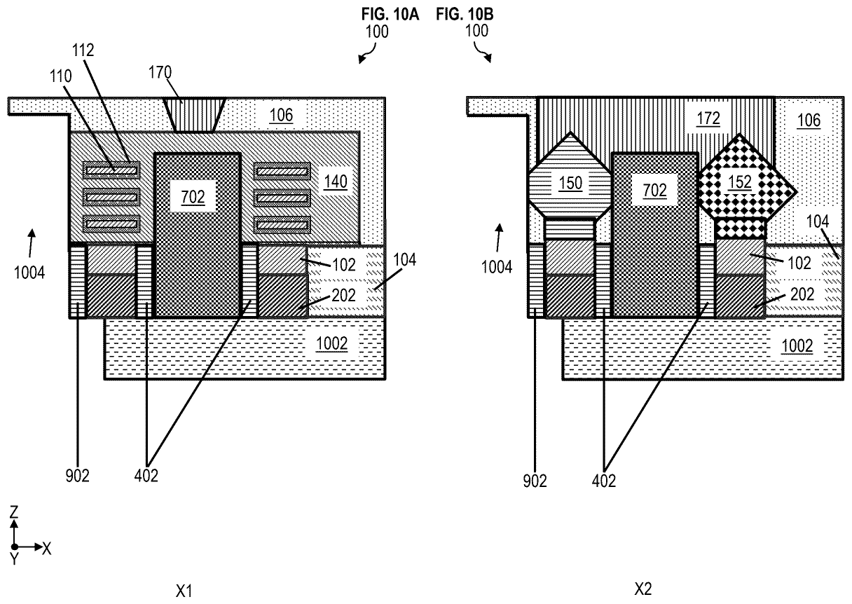

FIGS. 10A and 10B depict the IC 100 after a full cut on the PFET side. A block mask 1002 is deposited and patterned. The block mask 1002 can include any of the example materials of the block mask 302. Selective etching is performed to remove part of the ILD layer 106 and to break through the gate structure 140, thereby creating cavity 1004. This is a full cut because the etching is through the gate structure 140 to remove all the gate material along the edge. As seen in FIG. 8B, the etching also removes part of the overhang of the source/drain region 150 on the PFET.

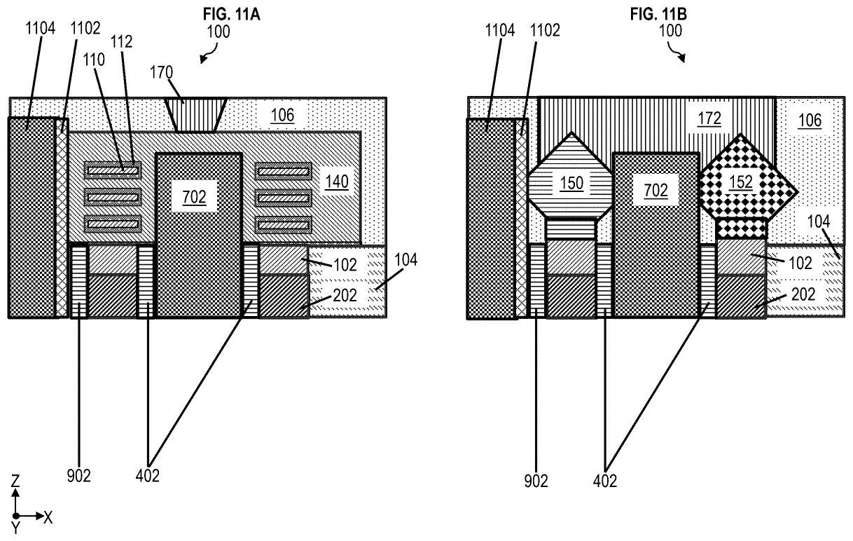

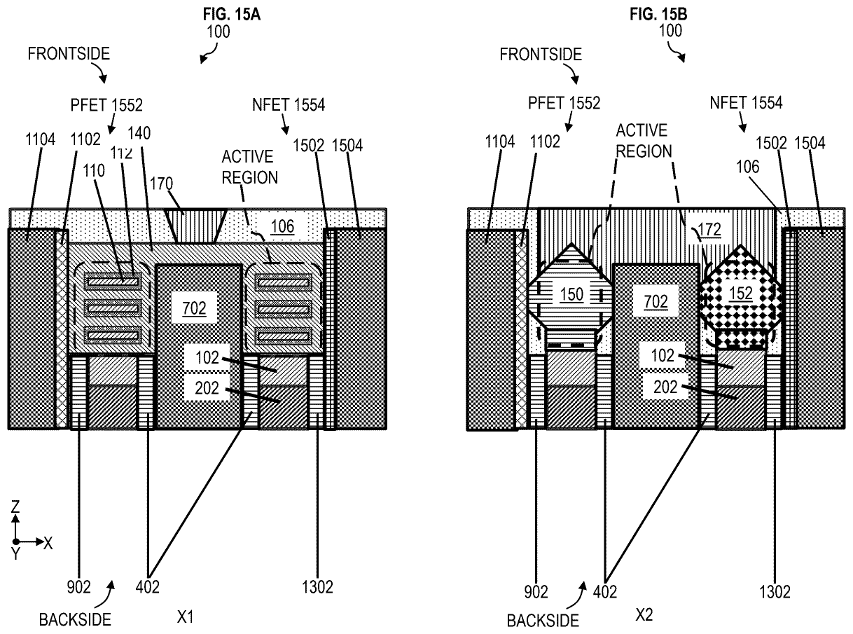

FIGS. 11A and 11B depict the IC 100 after formation of a stress liner on the PFET side. The block mask 1002 is removed. Optionally, deposition is performed to form a liner 1102 is a compressive stress liner or a tensile stress liner. The liner 1102 couples stress into the PFET channel to improve electrical current flow. Any suitable technique can be utilized to form the compressive stress liner. The liner 1102 can be a nitride material which can be deposited to induce compressive stress in the PFET. As will be seen in FIGS. 15A and 15B, a liner 1502 can optionally be deposited as a tensile stress liner to induce tensile stress in the NFET. In FIGS. 11A and 11B, the liner 1102 may also be referred to as a contact-etch-stop-layer (CESL) stressor. Deposition is performed to form a (outer) backside fill material 1104 to fill the cavity 1004 on the PFET. Although the liner 1102 is illustrated as an option, in one or more embodiments the liner 1102 may be omitted, and the backside fill material 1104 is present to fill the cavity without the liner 1102.

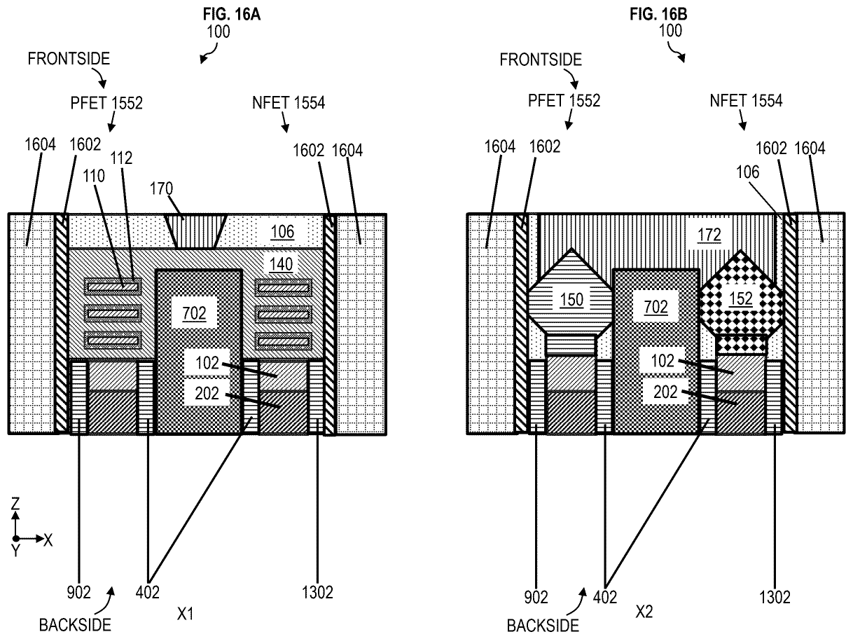

The materials of the (outer) backside fill material 1104 can include low-k dielectric materials, ultra-low-k dielectric materials, etc. The material of the (outer) backside fill material 1104 is intended to be a non-conducting material according to one or more embodiments. In one or more embodiments, the outer backside fill material can be a (outer) backside metal fill 1604 that is a conducting material as depicted in FIGS. 16A and 16B.

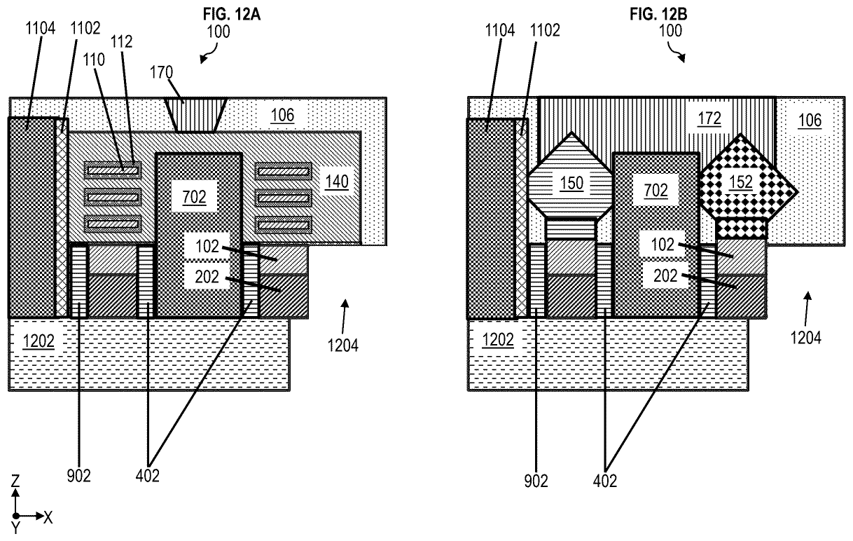

FIGS. 12A and 12B depict the IC 100 after block mask deposition and patterning and subsequent etching for the NFET. A block mask 1202 is deposited and patterned. The block mask 1202 can include any of the example materials of the block mask 302. Selective etching is performed to remove part of the STI region 104, thereby creating a cavity 1204. As seen in FIG. 12A, the etching stops on the gate structure 140 and the ILD layer 106 for the cavity 1204. As seen in FIG. 12B, the etching stops on the ILD layer 106 for the cavity 1204.

FIGS. 13A and 13B depict the IC 100 after outer backside spacer formation for the NFET. The block mask 1202 is removed. Spacer material is deposited conformally, and an anisotropic etch is performed to remove the spacer material from the horizontal surfaces, thereby forming (outer) backside spacer 1302 on the sidewalls of the cavity 1204. The thickness of the backside spacer 1302 in the x-axis determines the width/boundary of a cavity that is to be filled to form a subsequent outer backside cut fill material. The material of the backside spacer 1302 is to provide etch selectivity for subsequent etching.

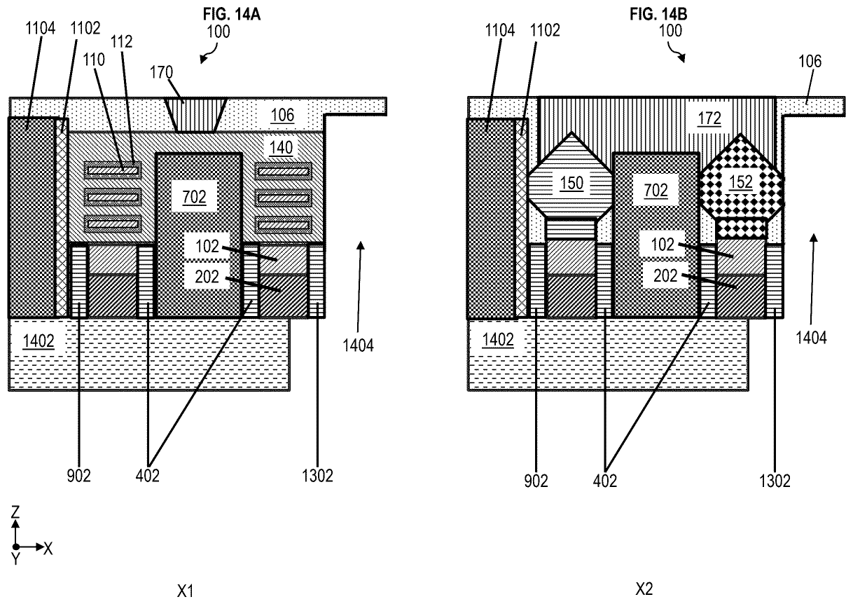

FIGS. 14A and 14B depict the IC 100 after a full cut on the NFET side. A block mask 1402 is deposited and patterned. The block mask 1402 can include any of the example materials of the block mask 302. Selective etching is performed to remove part of the ILD layer 106 and to break through the gate structure 140 in FIG. 14A, thereby creating cavity 1004. This is a full cut because the etching is through the gate structure 140 to remove all the gate material along the edge. As seen in FIG. 14B, the etching also removes part of the overhang of the source/drain region 152 on the NFET.

FIGS. 15A and 15B depict the IC 100 after formation of a stress liner on the NFET side. The block mask 1402 is removed. Optionally, deposition is performed to form a liner 1502 that is a tensile stress liner or a compressive stress liner. The liner 1502 couples stress into the NFET channel to improve electrical current flow. Any suitable technique can be utilized to form the tensile stress liner. The liner 1502 can be a nitride material which can be deposited to induce tensile stress in the NFET. As noted herein, the liner 1502 may also be referred to as a CESL stressor. Deposition is performed to form a (outer) backside fill material 1504 to fill the cavity 1404 on the NFET. Although the liner 1502 is illustrated as an option, in one or more embodiments the liner 1502 may be omitted, and the backside fill material 1504 is present to fill the cavity without the liner 1502.

The materials of the (outer) backside fill material 1504 can include low-k dielectric materials, ultra-low-k dielectric materials, etc. The material of the (outer) backside fill material 1504 is intended to be a non-conducting material according to one or more embodiments. In one or more embodiments, the outer backside fill material can be a (outer) backside metal fill 1604 that is a conducting material as depicted in FIGS. 16A and 16B.

As seen in FIGS. 15A and 15B, the capacitance outside of the active regions is reduced. The capacitance in the gate structure represented by dashed lines 160 (e.g., edge capacitance) and dashed lines 162 is reduced, because portions of the gate structure 140 are removed and replaced with a low-k dielectric material or ultra-low-k dielectric material. The (self-aligned inner) backside fill material 702, (self-aligned outer) backside fill material 1104, and (self-aligned outer) backside fill material 1504 all contribute to the reduction of the capacitance for the semiconductor structure.

According to one or more embodiments, FIGS. 16A and 16B depict the IC 100 after a metal fill instead of a low-k fill. In FIGS. 16A and 16B, it is now presumed that the etching is performed such that the cavity 1004 depicted in FIGS. 10A and 10B and the cavity 1404 depicted in FIGS. 14A and 14B extend further in the z-axis to the frontside. Deposition is performed to form liner 1602 using the (outer) backside spacers 902 and 1302 as guides. Deposition is performed to form the (outer) backside metal fill 1604 on both sides of the PFET and NFET. CMP can be performed to remove excess material and planarize.

The liner 1602 is a dielectric material that can be strained or unstrained. For unstrained dielectric material as the liner 1602, the cavities (corresponding to the cavity 1004 depicted in FIGS. 10A and 10B and the cavity 1404 in FIGS. 14A and 14B) can be formed simultaneously for the PFET and NFET, and the liner 1602 can be concurrently deposited for both the PFET and NFET. Then, the backside metal fill 1604 can be concurrently formed on both sides of the PFET and NFET.

In one or more embodiments, the liner 1602 can be formed to be a compressive stress liner and/or a tensile stress liner as discussed herein for liners 1102 and 1502. For example, the liner 1602 can be a compressive stress liner on the PFET, while the liner 1602 can be a tensile stress liner on the NFET. The materials of the backside metal fill 1604 can include metals, metal alloys, etc., so as to be a conducting fill material. The conducting fill materials can include copper (with a suitable liner), aluminum, gold, tantalum, tungsten, etc.

The backside metal fill 1604 can be utilized for signal routing or power routing, and the backside metal fill 1604 is insulated from the source/drain regions 150 and 152 and the gate structure 140 by the liner 1602. In one or more embodiments, the backside metal fill 1604 could be utilized as a decoupling capacitor.

According to one or more embodiments, FIGS. 17A and 17B depict the IC 100 after metal fill. Instead of filling the cavity 602 depicted in FIGS. 6A and 6B with a non-conducting low-k dielectric material or ultra-low-dielectric material, a conducting material is utilized. A liner 1702 is deposited in the cavity 602 depicted in FIGS. 6A and 6B, and a conducting material is deposited to form the (inner) backside metal fill 1704 in FIGS. 17A and 17B. CMP or etching can be performed to remove excess material. The backside metal fill 1704 can be utilized, for example, as a signal wire/conductor. The materials of the backside metal fill 1704 can include any materials of the backside metal fill 1604.

According to one or more embodiments, FIGS. 18A and 18B depict the IC 100 after a full cut and deposition of a fill material. In FIGS. 18A and 18B, it is now presumed that the etching is performed such that the cavity 602 depicted in FIGS. 6A and 6B extend further in the z-axis to the frontside. Accordingly, the gate cut is a full gate cut (i.e., the cavity 602 is extended) through the gate structure 140 separating the PFET gate and the NFET gate, thereby allowing independent gate control. In FIG. 18A, there are (two) gate contacts 170A and 170B instead of the (single) gate contact 170. The gate contacts 170A and 170B are on opposite sides of the gate cut in FIG. 18A. Deposition is performed to form the (inner) backside fill material 702. CMP can be performed to remove excess material and planarize.

According to one or more embodiments, FIGS. 19A and 19B depict the IC 100 after a full cut and deposition of a fill material. FIGS. 19A and 19B are analogous to FIGS. 17A and 17B in that the liner 1702 and backside metal fill 1704 are formed. However, instead of the partial gate cut in FIGS. 17A and 17B, a full gate cut is performed up into a portion of the ILD layer 106 in FIGS. 19A and 19B. FIGS. 19A and 19B are analogous to FIGS. 18A and 18B except the liner 1702 is deposited in the (extended) cavity 602 depicted in FIGS. 6A and 6B first, and then a conducting material is deposited to form the (inner) backside metal fill 1704 in FIGS. 19A and 19B.

According to one or more embodiments, FIGS. 20A and 20B depict the IC 100 after a full cut and deposition of a fill material. FIGS. 20A and 20B are analogous to FIGS. 19A and 19B. A RIE is performed for a full cut in the middle of the cell all the way to the frontside, which is analogous to an extended version in the z-axis of the cavity 602 depicted in FIGS. 6A and 6B. Deposition of the liner 1702 is performed, and deposition of the conducting material is performed for the (extended) backside metal fill 1704 in FIGS. 20A and 20B. The ILD layer 106 has additional ILD layer 106A on the frontside. After a wafer flip to process the frontside, lithography is performed to form an opening exposing a top surface of the backside metal fill 1704, and a contact via 2002 is formed. In FIGS. 20A and 20B, the (extended) backside metal fill 1704 can serve as a passthrough metal track for signal routing or power routing.

FIG. 21 depicts a cross-sectional view of an example backside cut having a realistic geometric shape according to one or more embodiments. In the IC 100, the backside fill material 702 and the backside metal fill 1704 can have the trapezoidal geometric shape illustrated in FIG. 21 after a backside cut, although a rectangular shape has been shown for illustrative purposes. As such, the cavity 602 depicted in FIGS. 6A and 6B would have the trapezoidal geometric shape illustrated in FIG. 21 prior to deposition of any fill material, liner, etc. The representation of the trapezoidal geometric shape for the backside fill material 702 and the backside metal fill 1704 denotes a backside cut with fill material, in which the trapezoidal geometric shape is wider in the x-axis at the backside than at the frontside. This characterizes a backside cut into the material that is filled with appropriate fill materials.

Turning now, according to one or more embodiments, to a method of forming a portion of the IC 100 includes providing a first transistor (e.g., PFET 1552 or NFET 1554) having a gate structure 140. The method includes providing a second transistor (e.g., NFET 1554 or PFET 1552) having the gate structure 140, the gate structure 140 including an upper portion 650 and a lower portion 652, where the upper portion 650 includes a first bottom surface (e.g., bottom surface 610) and is outside an active region of the first transistor and the second transistor (e.g., PFET 1552 and NFET 1554), the upper portion 650 being between the first transistor and the second transistor, where the lower portion 652 includes a second bottom surface (e.g., bottom surface 612) and is inside the active region of the first transistor and the second transistor.

Further, the first transistor and the second transistor include channel regions (e.g., (respective) semiconductor layers 110 for the PFET 1552 and NFET 1554), the second bottom surface extending underneath the channel regions (e.g., (respective) semiconductor layers 110 for the PFET 1552 and NFET 1554). The first bottom surface is vertically above the second bottom surface (e.g., the bottom surface 610 is vertically above the bottom surface 612).

In one or more embodiments, non-conducting fill material (e.g., backside fill material 702 or liner 1702) is underneath the upper portion 650, the non-conducting fill material (e.g., backside fill material 702 or liner 1702) being outside the active region of the first transistor and the second transistor (e.g., PFET 1552 and NFET 1554). Additionally, the non-conducting fill material (e.g., liner 1702 depicted in FIGS. 17A, 17B, 19A, 19B, 20A, 20B) is around a metal fill material (e.g., backside metal fill 1704).

Further, backside spacers (e.g., backside spacers 402) are formed on a side(s) of a substrate 102, the first transistor and the second transistor being above the substrate 102; and a boundary between the upper portion 650 and the lower portion 652 of the gate structure 140 is self-aligned to the backside spacers (e.g., backside spacers 402).

Additionally, a non-conducting fill material (e.g., liners 1102 and 1502) is formed on a side of the gate structure 140 so as to be laterally displaced from the upper portion 650. The non-conducting fill material (e.g., liners 1102 and/or 1502) comprises compressive stress. The non-conducting fill material (e.g., liners 1102 and 1502) comprises tensile stress.

The first transistor comprises a source/drain region (e.g., source/drain regions 150 and 152), a first non-conducting fill material (e.g., liners 1102 and 1502) is formed on a sidewall of the source/drain region so as to be self-aligned with a backside spacer (e.g., (outer) backside spacers 902 and 1302), the non-conducting fill material (e.g., liners 1102 and 1502) comprises compressive or tensile stress.

Turning now, according to one or more embodiments, to a method of forming a portion of the IC 100 includes providing a first transistor and a second transistor (e.g., PFET 1552 and NFET 1554) having a gate structure 140, the first transistor having a first channel region (e.g., (first) semiconductor layers 110 of the PFET 1152), the second transistor having a second channel region (e.g., (second) semiconductor layers 110 of the NFET 1154). The method includes forming a non-conducting fill material (e.g., backside fill material 702) in a cavity 602 of the gate structure 140 between the first transistor (e.g., PFET 1552) and the second transistor (e.g., NFET 1554), forming a liner (e.g., liners 1102 and 1502) on a side of the gate structure 140 so as to be laterally displaced from the non-conducting fill material (e.g., backside fill material 702), and forming a metal fill material (e.g., (outer) backside metal fill 1604) on the liner such that the first channel region (e.g., (first) semiconductor layers 110 of the PFET 1152) intervenes between the metal fill material ((outer) backside metal fill 1604) and the non-conducting fill material (e.g., backside fill material 702).

Additionally, the liner (e.g., liners 1102 and 1502) is self-aligned to a first backside spacer (e.g., backside spacers 902 and 1302) and the non-conducting fill material is self-aligned to a second backside spacer (e.g., e.g., backside spacers 402).

As discussed herein, gate material is formed around the semiconductor layers. The gate material includes high-k material and work function material generally referred to as a high-k metal gate (HKMG). Techniques for forming HKMG in gate openings are well-known in the art and, thus, the details have been omitted in order to allow the reader to focus on the salient aspects of the disclosed methods. However, it should be understood that such HKMG will generally include formation of one or more gate dielectric layers (e.g., an inter-layer (IL) oxide and a high-k gate dielectric layer), which are deposited so as to line the gate openings, and formation of one or more metal layers, which are deposited onto the gate dielectric layer(s) so as to fill the gate openings. The materials and thicknesses of the dielectric and metal layers used for the HKMG can be preselected to achieve desired work functions given the conductivity type of the FET. To avoid clutter in the drawings and to allow the reader to focus on the salient aspects of the disclosed methods, the different layers within the HKMG stack are not illustrated. For explanation purposes, a high-k gate dielectric layer can be, for example, a dielectric material with a dielectric constant that is greater than the dielectric constant of silicon dioxide (i.e., greater than 3.9). Exemplary high-k dielectric materials include, but are not limited to, hafnium (Hf)-based dielectrics (e.g., hafnium oxide, hafnium silicon oxide, hafnium silicon oxynitride, hafnium aluminum oxide, etc.) or other suitable high-k dielectrics (e.g., aluminum oxide, tantalum oxide, zirconium oxide, etc.). Optionally, the metal layer(s) can include a work function metal that is immediately adjacent to the gate dielectric layer and that is preselected in order to achieve an optimal gate conductor work function given the conductivity type of the nanosheet-FET. For example, the optimal gate conductor work function for the PFETs can be, for example, between about 4.9 eV and about 5.2 eV. Exemplary metals (and metal alloys) having a work function within or close to this range include, but are not limited to, ruthenium, palladium, platinum, cobalt, and nickel, as well as metal oxides (aluminum carbon oxide, aluminum titanium carbon oxide, etc.) and metal nitrides (e.g., titanium nitride, titanium silicon nitride, tantalum silicon nitride, titanium aluminum nitride, tantalum aluminum nitride, etc.). The optimal gate conductor work function for NFETs can be, for example, between 3.9 eV and about 4.2 eV. Exemplary metals (and metal alloys) having a work function within or close to this range include, but are not limited to, hafnium, zirconium, titanium, tantalum, aluminum, and alloys thereof, such as, hafnium carbide, zirconium carbide, titanium carbide, tantalum carbide, and aluminum carbide. The metal layer(s) can further include a fill metal or fill metal alloy, such as tungsten, a tungsten alloy (e.g., tungsten silicide or titanium tungsten), cobalt, aluminum, or any other suitable fill metal or fill metal.

Although not shown, contact formation and ILD formation are performed. ILD material can be deposited, source/drain contact openings are patterned by conventional lithography, and then metal is deposited to fill the cavities thereby forming metal contacts. A portion of the metal contacts may include silicide, resulting from the interface of the metal material and semiconductor material. The metal contacts are source/drain contacts that are respectively connected to epitaxial source/drain regions.

The ILD material can be SiO₂, SiN, a low-k dielectric material or an ultra-low-k dielectric material. Low-k dielectric materials may generally include dielectric materials having a k value of about 3.9 or less. The ultra-low-k dielectric material generally includes dielectric materials having a k value less than 2.5. Unless otherwise noted, all k values mentioned in the present application are measured relative to a vacuum. Exemplary ultra-low-k dielectric materials generally include porous materials such as porous organic silicate glasses, porous polyamide nanofoams, silica xerogels, porous hydrogen silsequioxane (HSQ), porous methylsilsesquioxane (MSQ), porous inorganic materials, porous CVD materials, porous organic materials, or combinations thereof. The ultra-low-k dielectric material can be produced using a templated process or a sol-gel process as is generally known in the art. In the templated process, the precursor typically contains a composite of thermally labile and stable materials. After film deposition, the thermally labile materials can be removed by thermal heating, leaving pores in the dielectric film. In the sol gel process, the porous low-k dielectric films can be formed by hydrolysis and polycondensation of an alkoxide(s) such as tetraetehoxysilane (TEOS).

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The phrase “selective to,” such as, for example, “a first element selective to a second element,” means that the first element can be etched and the second element can act as an etch stop.

As used herein, “p-type” refers to the addition of impurities to an intrinsic semiconductor that creates deficiencies of valence electrons. In a silicon-containing substrate, examples of p-type dopants, i.e., impurities, include but are not limited to: boron, aluminum, gallium and indium.

As used herein, “n-type” refers to the addition of impurities that contributes free electrons to an intrinsic semiconductor. In a silicon containing substrate examples of n-type dopants, i.e., impurities, include but are not limited to antimony, arsenic and phosphorous.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

As noted above, atomic layer etching processes can be used in the present invention for via residue removal, such as can be caused by via misalignment. The atomic layer etch process provide precise etching of metals using a plasma-based approach or an electrochemical approach. The atomic layer etching processes are generally defined by two well-defined, sequential, self-limiting reaction steps that can be independently controlled. The process generally includes passivation followed selective removal of the passivation layer and can be used to remove thin metal layers on the order of nanometers. An exemplary plasma-based approach generally includes a two-step process that generally includes exposing a metal such a copper to chlorine and hydrogen plasmas at low temperature (below 20° C.). This process generates a volatile etch product that minimizes surface contamination. In another example, cyclic exposure to an oxidant and hexafluoroacetylacetone (Hhfac) at an elevated temperature such as at 275° C. can be used to selectively etch a metal such as copper. An exemplary electrochemical approach also can include two steps. A first step includes surface-limited sulfidization of the metal such as copper to form a metal sulfide, e.g., Cu₂S, followed by selective wet etching of the metal sulfide, e.g., etching of Cu₂S in HCl. Atomic layer etching is relatively recent technology and optimization for a specific metal is well within the skill of those in the art. The reactions at the surface provide high selectivity and minimal or no attack of exposed dielectric surfaces.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The photoresist can be formed using conventional deposition techniques such chemical vapor deposition, plasma vapor deposition, sputtering, dip coating, spin-on coating, brushing, spraying and other like deposition techniques can be employed. Following formation of the photoresist, the photoresist is exposed to a desired pattern of radiation such as X-ray radiation, extreme ultraviolet (EUV) radiation, electron beam radiation or the like. Next, the exposed photoresist is developed utilizing a conventional resist development process.

After the development step, the etching step can be performed to transfer the pattern from the patterned photoresist into the interlayer dielectric. The etching step used in forming the at least one opening can include a dry etching process (including, for example, reactive ion etching, ion beam etching, plasma etching or laser ablation), a wet chemical etching process or any combination thereof.

For the sake of brevity, conventional techniques related to making and using aspects of the invention may or may not be described in detail herein. In particular, various aspects of computing systems and specific computer programs to implement the various technical features described herein are well known. Accordingly, in the interest of brevity, many conventional implementation details are only mentioned briefly herein or are omitted entirely without providing the well-known system and/or process details.

In some embodiments, various functions or acts can take place at a given location and/or in connection with the operation of one or more apparatuses or systems. In some embodiments, a portion of a given function or act can be performed at a first device or location, and the remainder of the function or act can be performed at one or more additional devices or locations.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The present disclosure has been presented for purposes of illustration and description but is not intended to be exhaustive or limited to the form disclosed. Many modifications and variations will be apparent to those of ordinary skill in the art without departing from the scope and spirit of the disclosure. The embodiments were chosen and described in order to best explain the principles of the disclosure and the practical application, and to enable others of ordinary skill in the art to understand the disclosure for various embodiments with various modifications as are suited to the particular use contemplated.

The diagrams depicted herein are illustrative. There can be many variations to the diagram or the steps (or operations) described therein without departing from the spirit of the disclosure. For instance, the actions can be performed in a differing order or actions can be added, deleted or modified. Also, the term “coupled” describes having a signal path between two elements and does not imply a direct connection between the elements with no intervening elements/connections therebetween. All of these variations are considered a part of the present disclosure.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e., one, two, three, four, etc. The terms “a plurality” are understood to include any integer number greater than or equal to two, i.e., two, three, four, five, etc. The term “connection” can include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A semiconductor structure comprising:
a first transistor having a gate structure; and
a second transistor having the gate structure, the gate structure comprising an upper portion and a lower portion, wherein the upper portion comprises a first bottom surface and is outside an active region of the first transistor and the second transistor, the upper portion being between the first transistor and the second transistor, wherein the lower portion comprises a second bottom surface and is inside the active region of the first transistor and the second transistor.

2. The semiconductor structure of claim 1, wherein the first transistor and the second transistor comprise channel regions, the second bottom surface extending underneath the channel regions.

3. The semiconductor structure of claim 1, wherein the first bottom surface is vertically above the second bottom surface.

4. The semiconductor structure of claim 1, wherein a non-conducting fill material is underneath the upper portion, the non-conducting fill material being outside the active region of the first transistor and the second transistor.

5. The semiconductor structure of claim 4, wherein the non-conducting fill material is around a metal fill material.

6. The semiconductor structure of claim 1, wherein:
backside spacers are formed on a side of a substrate, the first transistor and the second transistor being above the substrate; and
a boundary between the upper portion and the lower portion of the gate structure is self-aligned to the backside spacers.

7. The semiconductor structure of claim 1, wherein a non-conducting fill material is formed on an edge of the gate structure so as to be laterally displaced from the upper portion.

8. The semiconductor structure of claim 7, wherein the non-conducting fill material comprises compressive stress or tensile stress.

9. The semiconductor structure of claim 1, wherein:
the first transistor comprises a first source/drain region and the second transistor comprises a second source/drain region; and
a first non-conducting fill material is formed between the first source/drain region and the second source/drain region so as to be self-aligned to first backside spacers, the first non-conducting fill material being formed underneath the upper portion.

10. The semiconductor structure of claim 9, wherein:
a second non-conducting fill material is formed on a sidewall of the first source/drain region so as to be self-aligned with another backside spacer, the second non-conducting fill material being laterally displaced from the first non-conducting fill material; and
the second non-conducting fill material comprises compressive or tensile stress.

11. A method comprising:
providing a first transistor having a gate structure; and
providing a second transistor having the gate structure, the gate structure comprising an upper portion and a lower portion, wherein the upper portion comprises a first bottom surface and is outside an active region of the first transistor and the second transistor, the upper portion being between the first transistor and the second transistor, wherein the lower portion comprises a second bottom surface and is inside the active region of the first transistor and the second transistor.

12. The method of claim 11, wherein the first transistor and the second transistor comprise channel regions, the second bottom surface extending underneath the channel regions.

13. The method of claim 11, wherein the first bottom surface is vertically above the second bottom surface.

14. The method of claim 11, wherein a non-conducting fill material is underneath the upper portion, the non-conducting fill material being outside the active region of the first transistor and the second transistor.

15. The method of claim 14, wherein the non-conducting fill material is around a metal fill material.

16. The method of claim 11, wherein:
backside spacers are formed on a side of a substrate, the first transistor and the second transistor being above the substrate; and
a boundary between the upper portion and the lower portion of the gate structure is self-aligned to the backside spacers.

17. The method of claim 11, wherein a non-conducting fill material is formed on an edge of the gate structure so as to be laterally displaced from the upper portion.

18. The method of claim 17, wherein the non-conducting fill material comprises compressive stress and tensile stress.

19. The method of claim 11, wherein:
the first transistor comprises a source/drain region and the second transistor comprises a second source/drain region; and
a first non-conducting fill material is formed between the first source/drain region and the second source/drain region so as to be self-aligned to first backside spacers, the first non-conducting fill material being formed underneath the upper portion.

20. The method of claim 19, wherein:
a second non-conducting fill material is formed on a sidewall of the first source/drain region so as to be self-aligned with another backside spacer, the second non-conducting fill material being laterally displaced from the first non-conducting fill material; and
the second non-conducting fill material comprises compressive or tensile stress.

21. A semiconductor structure comprising:
a first transistor and a second transistor having a gate structure, the first transistor having a first channel region, the second transistor having a second channel region;
a non-conducting fill material formed in a cavity of the gate structure between the first transistor and the second transistor;
a liner formed on an edge of the gate structure so as to be laterally displaced from the non-conducting fill material; and
a metal fill material formed on the liner such that the first channel region intervenes between the metal fill material and the non-conducting fill material.

22. A method comprising:
providing a first transistor and a second transistor having a gate structure, the first transistor having a first channel region, the second transistor having a second channel region;
forming a non-conducting fill material in a cavity of the gate structure between the first transistor and the second transistor;
forming a liner on an edge of the gate structure so as to be laterally displaced from the non-conducting fill material; and
forming a metal fill material on the liner such that the first channel region intervenes between the metal fill material and the non-conducting fill material.

23. A semiconductor structure comprising:
a first transistor and a second transistor having a gate structure on a substrate, the first transistor having a first channel region, the second transistor having a second channel region;
a non-conducting fill material formed between the first transistor and the second transistor separating the gate structure into a first side for the first transistor and a second side for the second transistor, the non-conducting fill material being formed through the gate structure from a backside to a frontside of the substrate and being self-aligned to backside spacers; and
a first gate contact formed on the first side and a second gate contact formed on the second side.

24. The semiconductor structure of claim 23, further comprising a metal fill material extending through the non-conducting fill material from the backside to the frontside; and
a contact via formed in contact with the metal fill material on the frontside.

25. The semiconductor structure of claim 23, wherein the non-conducting fill material is around a metal fill material.
